(19) United States
(12) Patent Application Publication
(10) Pub. No.: US 2012/0319185 A1
(43) Pub. Date: Dec. 20, 2012

(54) NAND STRUCTURE AND METHOD OF MANUFACTURING THE SAME

(75) Inventors: Qingqing Liang, Beijing (CN); Huicai Zhong, Beijing (CN); Huilong Zhu, Poughkeepsie, NY (US)

(73) Assignee: INSTITUTE OF MICROELECTRONICS, CHINESE ACADEMY OF SCIENCES, BEIJING (CN)

(21) Appl. No.: 13/063,653

(22) PCT Filed: Jun. 25, 2010
(86) PCT No.: PCT/CN10/74486

§ 371 Date: Mar. 11, 2011

(30) Foreign Application Priority Data
Nov. 25, 2009 (CN) 200910241209.6

(51) Int. Cl. H01L 29/78; H01L 21/336

(52) U.S. Cl. 257/314; 438/283; 257/E29.255; 257/E21.409

(57) ABSTRACT

The present invention provides a NAND gate structure, comprising: a substrate; a gate insulation layer formed on the substrate; a source/drain region formed in the substrate; a middle gate formed on the gate insulator layer, a first gate and a second gate on each side of the middle gate, first sidewall spacers between the first gate and the middle gate and between the second gate and the middle gate, and second sidewall spacers outside the first gate and the second gate, wherein, a first contact hole region is provided on the middle gate, second contact hole regions are provided respectively on the first gate and the second gate, and the first contact hole region and the second contact hole regions are in staggered arrangement. The present invention proposes a new NAND structure and a method of manufacturing the same. With the NAND structure, about 30-50% area of the chip may be effectively reduced.

### FIELD OF THE INVENTION

The present invention relates to the technical field of semiconductor design and manufacture, and particularly, relates to a self-aligned small size NAND structure and a method of manufacturing the same.

### BACKGROUND OF THE INVENTION

NAND structure is commonly used in flash memory, and NAND flash memory is better than Hard Disk Drive. As people are continuing to pursue products of lower power consumption, less weight but better performance, NAND is widely used because it has the advantages of higher cell density, higher storage density, faster write and erase speed, and so forth. Having a cell size almost only half of that of a NOR device cell, NAND flash memory can provide higher capacity than NOR device in a given mould size and has very fast write and erase speed. The main function of NAND flash memory is for data storage. At present, it is mainly used in flash memory cards of, for example, digital camera etc., and MP3 players.

The problem of the prior art is that, with the need of small-sized digital devices, the requirements to the size and storage capacity of memory cards are higher and higher. Therefore, how to design smaller-sized NAND structure becomes an urgent problem to be solved.

### SUMMARY OF THE INVENTION

The present invention aims to solve at least one of the technical defects mentioned above, especially, to diminish the size of NAND structure so as to reduce the size of storage card and further enlarge its storage capacity.

In order to achieve the aims mentioned above, in one aspect, the present invention provides a NAND gate structure, comprising: a substrate; a gate insulation layer formed on the substrate; a source/drain region formed in the substrate; a middle gate formed on the gate insulation layer, a first gate and a second gate on each side of the middle gate, first sidewall spacers between the first gate and the middle gate and between the second gate and the middle gate, and second sidewall spacers outside the first gate and the second gate, wherein, a first contact hole region is provided on the middle gate, the second contact hole regions are provided respectively on the first gate and the second gate, and the first contact hole region and the second contact hole regions are in staggered arrangement.

In one embodiment of the present invention, the thickness of the first sidewall spacer is less than that of the second sidewall spacer.

In one embodiment of the present invention, the thickness of the first sidewall spacer is 2-10 nm.

In one embodiment of the present invention, the first contact hole region is connected with the middle gate through a first metal or polysilicon, wherein, at least a part of the first metal or polysilicon under the first contact hole region is higher than the first metal or polysilicon outside the first contact hole region.

In one embodiment of the present invention, the second contact hole regions are connected with the first gate and the second gate through a second metal or polysilicon, wherein, at least a part of the second metal or polysilicon under the second contact hole regions are higher than the second metal or polysilicon outside the second contact hole regions.

In one embodiment of the present invention, the NAND gate structure further comprises: forming third contact hole regions, respectively, on the source/drain region, which are connected with the source/drain region through a third metal, wherein, at least a part of the third metal under the third contact hole regions are higher than the third metal outside the third contact hole regions.

In one embodiment of the present invention, a metallic silicide layer is also comprised between the source/drain region and the third metal.

In one embodiment of the present invention, the first metal or polysilicon, the second metal or polysilicon, or the third metal has an L-shaped or T-shaped contact.

In one embodiment of the present invention, the third metal is W, Al, or Cu.

In one embodiment of the present invention, the first metal or second metal is Ti, TiN, TiAlN or Al.

In another aspect, the present invention provides a storage device comprising a plurality of the above-mentioned NAND structures.

A further embodiment of the present invention provides a method of manufacturing a NAND structure, comprising the following steps: forming a substrate; forming a gate insulation layer on the substrate; forming on the gate insulation layer a middle gate, and forming a first gate and a second gate on both sides of the middle gate, wherein first sidewall spacers are formed between the first gate and the middle gate and between the second gate and the middle gate, and second sidewall spacers are formed outside the first gate and the second gate; forming a source/drain region in the substrate; forming a first contact hole region on the middle gate, second contact hole regions on the first gate and the second gate, and third contact hole regions on the source/drain region, wherein the first contact hole region and the second contact hole regions are in staggered arrangement.

In one embodiment of the present invention, forming the first gate and the second gate comprises the following steps: forming the first sidewall spacers on both sides of the middle gate, and then depositing the second gate metal or polysilicon; carrying out scattering implantation to the deposited second metal or multicrystal silicon to planarize the top of the second gate metal or polysilicon on the middle gate; forming the first gate and the second gate by anisotropically etching the second gate metal or polysilicon, and exposing the middle gate.

In one embodiment of the present invention, the thickness of the first sidewall spacer is smaller than that of the second sidewall spacer.

In one embodiment of the present invention, the thickness of the first sidewall spacer is 2-10 nm.

In one embodiment of the present invention, the first contact hole region is connected with the middle gate through a first metal or polysilicon, wherein, at least a part of the first metal or polysilicon under the first contact hole region is higher than the first metal or polysilicon outside the first contact hole region.

In one embodiment of the present invention, the second contact hole region is connected with the first gate and the second gate through a second metal or polysilicon, wherein, at least a part of the second metal or polysilicon under the second contact hole regions are higher than the second metal or polysilicon outside the second contact hole regions.

In one embodiment of the present invention, the third contact hole regions are connected with the source/drain region through a third metal, wherein, at least a part of the third metal under the third contact hole regions is higher than the third metal outside the third contact hole regions.

In one embodiment of the present invention, further comprises: forming a metallic silicide layer between the source/drain region and the third metal.

In one embodiment of the present invention, the first metal or polysilicon, the second metal or polysilicon, or the third metal has an L-shaped or T-shaped contact.

In one embodiment of the present invention, the third metal is W, Al, or Cu.

In one embodiment of the present invention, the first metal or second metal is Ti, TiN, TiAlN or Al.

The present invention provides a new NAND structure and a method of manufacturing the same. With the NAND structure, about 30-50% area of the chip may be effectively reduced. Furthermore, embodiments of the present invention apply self-aligned contact hole forming technology, therefore, additional contact hole landing pad is not needed. At the same time, the embodiments illustrated by the present invention are substantially suitable for any current advanced VLSI CMOS technique, for example HKMG (high-K metal gate) or PolySiON (polysilicon/silicon oxynitride), gate-first or gate-last technique and so on, therefore, the NAND structure and the manufacturing method thereof provided by the present invention have universal applications.

Additional aspects and advantages of the present invention will be described in the following, some of which will become clear by the description or be understood while practicing.

### BRIEF DESCRIPTION OF THE DRAWINGS

The above-mentioned and/or additional aspects and advantages of the present invention will become clear and be easily understood by describing the embodiments with reference to the drawings as follows, wherein:

FIG. 1 and FIG. 2 are the cross-section view and the top view of the NAND structure in the embodiments of the present invention, respectively;

FIG. 3 is a schematic diagram of standard NAND structure in prior art;

FIG. 4 is a schematic diagram of the NAND structure in the embodiments of the present invention;

FIGS. 5-17 are schematic diagrams illustrating the intermediate steps of forming the NAND structure in the embodiments of the present invention.

### DETAILED DESCRIPTION OF THE INVENTION

The embodiments of the present invention will be described in detail as follows and the examples therein will be illustrated in the drawings, wherein, from beginning to end, identical or similar reference numbers represent identical or similar element or elements having identical or similar functions. The following embodiments described with reference to the drawings are illustrative and only used to explain the present invention, but may not be interpreted as the restrictions of this invention.

The following disclosure provides a plurality of different embodiments or examples to achieve different structures of the present invention. To simplify the disclosure of the present invention, description of the components and arrangements of specific examples is given below. Of course, they are only illustrative and not limiting the present invention. Moreover, in the present invention, reference numbers and/or letters may be repeated in different embodiments. Such repetition is for the purposes of simplification and clearness, and does not denote the relationship between different embodiments and/or arrangements being discussed. In addition, the present invention provides various examples of specific process and materials. However, it is obvious for a person of ordinary skill in the art that other process and/or materials may alternatively be utilized. Furthermore, the following structure in which a first object is “on” a second object may include an embodiment in which the first object and the second object are formed to be in direct contact with each other, and may also include an embodiment in which another object is formed between the first object and the second object such that the first and second objects might not be in direct contact with each other.

The present invention provides a new NAND structure and a method of manufacturing the same. In the embodiments of the present invention, the structure comprises a middle gate, a first gate and a second gate on each side of the middle gate, wherein, the middle gate is separated from the first gate and the second gate by first sidewall spacers, and thereby the middle gate, the first gate and the second gate all together compose control gates of the channel between the source region and the drain region, and thus realizes the purpose of NAND. In one embodiment of the present invention, the thickness of the first sidewall spacers may not be too large, preferably, is about 2-10 nm. With the NAND structure in the embodiments of the present invention, about 30-50% area of the chip may be effectively reduced.

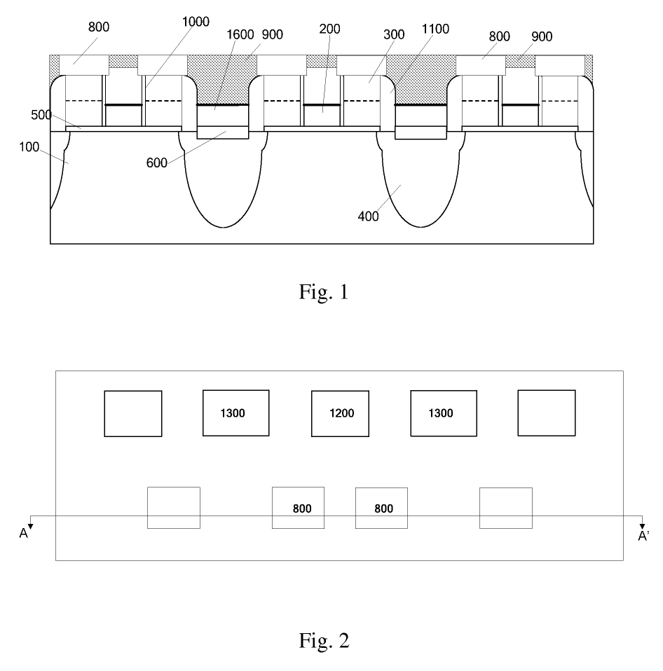

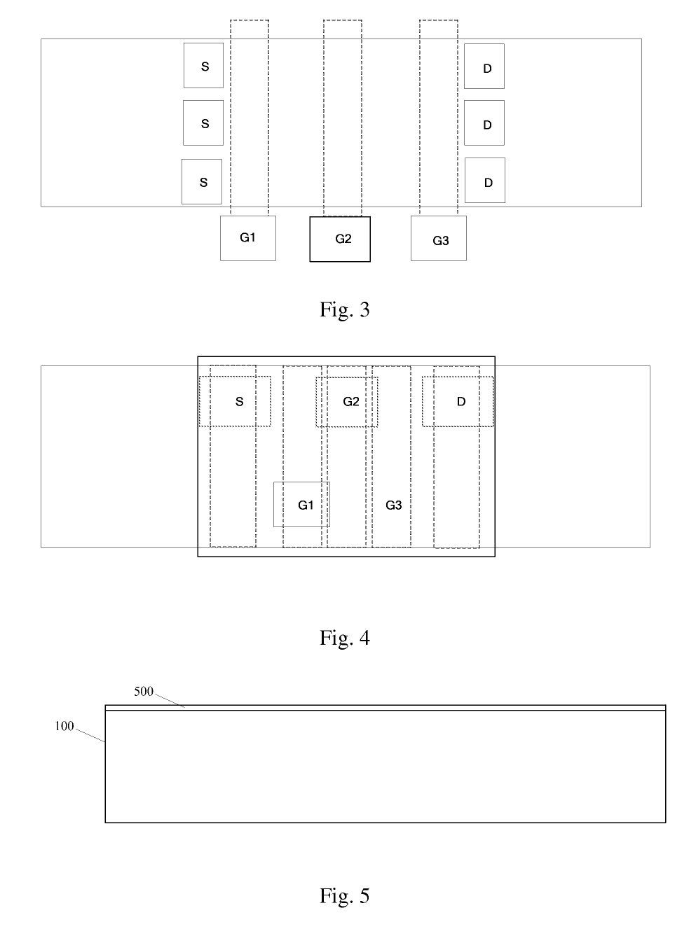

FIG. 1 and FIG. 2 are the cross-section view and top view of the NAND structure, respectively, in the embodiments of the present invention. The cross-section view of FIG. 1 is the cross-sectional view along A-A′ line of the top view of FIG. 2. It is necessary to indicate that the drawings in each embodiment of the present invention are only illustrative, so they are not necessary to be drawn in proportion. The structure comprises a substrate 100, a gate insulation layer 500 formed on the substrate, and a source/drain region 400, and a middle gate 200 and a first and second gates 300 formed on the gate insulation layer 500, and a metallic silicide layer 600 formed on the source/drain region 400 and a third metal 1600, wherein the substrate 100 may include any semiconductor substrate material as appropriate, and more specifically, may include, but is not limit to, silicon, germanium, silicon germanium, SOI (silicon on insulator), silicon carbide, gallium arsenide or any III/V group compound semiconductor. In the embodiments of the present invention, first sidewall spacers 1000 are formed between the first and second gates 300 and the middle gate 200, and second sidewall spacers 1100 are formed outside the first and second gates 300. The width of the second sidewall spacers 1100 is bigger than that of the first sidewall spacers 1000. A first contact hole region 1200 of a first layer metal is provided on the middle gate 200, second contact hole regions 800 of a first layer metal are provided on the first and second gates 300, and third contact hole regions 1300 of a first layer metal are provided on the source/drain region 400, wherein, the first contact hole region 1200 and the second contact hole region 800 are in staggered arrangement, and hence the area of the NAND structure can be greatly reduced. FIG. 3 is the schematic diagram of a standard NAND structure in the prior art and FIG. 4 is the schematic diagram of the NAND structure in the embodiments of the present invention. By comparing the two Figs, it can be seen that the NAND structure provided by the present invention has smaller area.

Furthermore, in the embodiments of the present invention, a part of the first metal or polysilicon forming the middle gate 200 outside the first contact hole region 1200 is etched away by self-aligned technology so that at least a part of the first metal or polysilicon under the first contact hole region 1200 is higher than the first metal or polysilicon outside the first contact hole region 1200, that is, having an L-shaped or T-shaped contact. In the same way, a part of the second metal or polysilicon forming the first and second gates 300 outside the second contact hole regions 800 is etched away so that at least a part of the second metal or polysilicon under the second contact hole regions 800 is higher than the second metal or polysilicon outside the second contact hole regions 800. Similarly, a part of the third metal 1600 outside the third contact hole regions 1300 is etched so that at least a part of the third metal under the third contact hole regions 1300 is higher than the third metal 1600 outside the third contact hole regions 1300.

In the embodiments of the present invention, a storage device is proposed, comprising several the above-mentioned new NAND structures, and hence the area of the memory chip is greatly reduced and the memory capacity is enlarged.

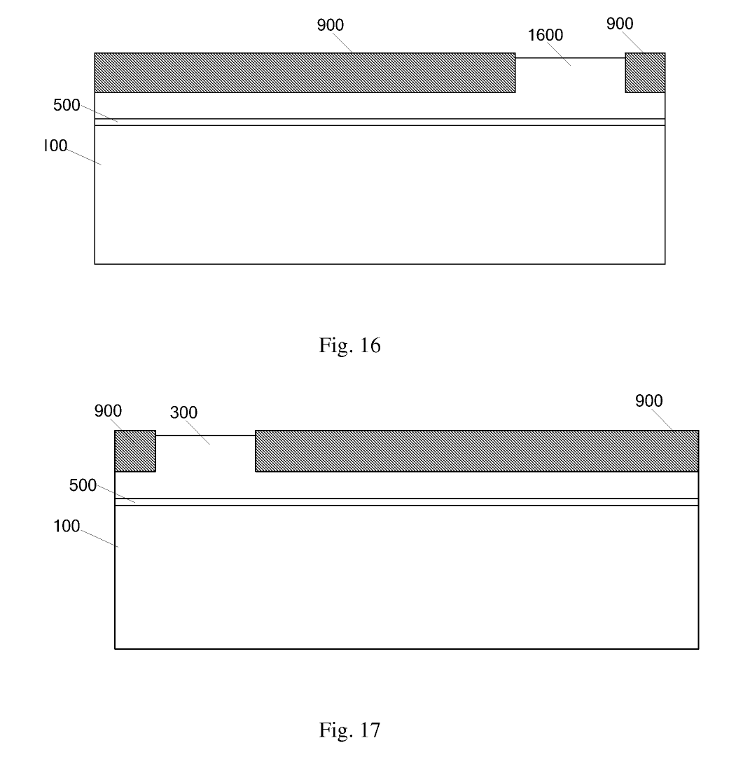

FIGS. 5-17 are schematic diagrams of the intermediate steps of forming the NAND structure in the embodiments of the present invention, comprising the following steps:

In step 1, a substrate 100 is provided, and a gate insulator layer 500 is formed on the substrate 100, as shown in FIG. 5, wherein, in one embodiment of the present invention, the gate insulator layer 500 comprises, but is not limit to, nitride, oxide, oxy-nitride or high-k dielectric material.

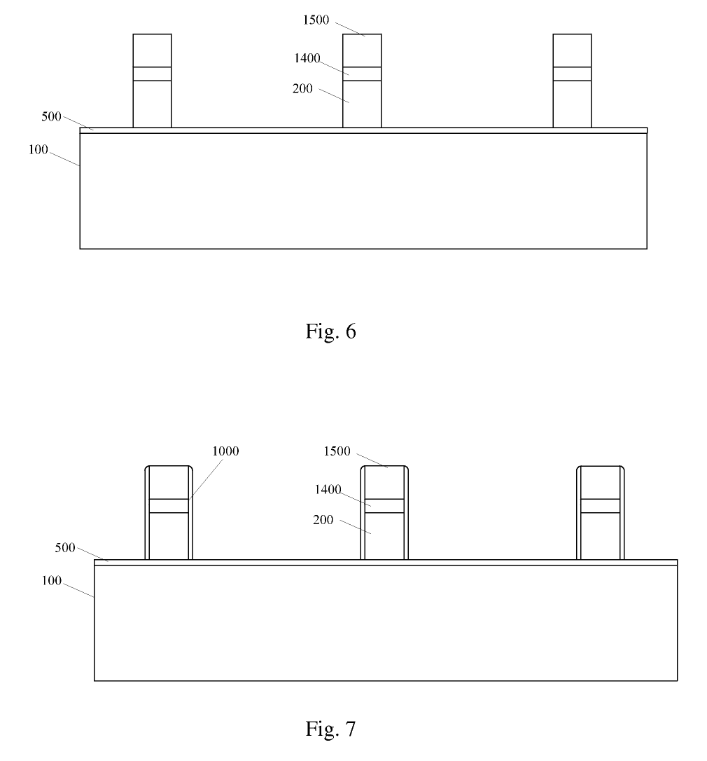

In step 2, a middle gate stack is formed, comprising a middle gate 200, an oxide layer 1400 and a non-metal capping layer 1500, as shown in FIG. 6. Specifically, the middle gate stack is formed by sequentially depositing the middle gate layer 200, the oxide layer 1400 and the non-metal capping layer 1500 on the gate insulation layer 500, and then patterning them. In one embodiment of the present invention, oxide layer 1400 comprises LTO (low temperature oxide). In other embodiments, non-metal capping layer 1500 comprises SiGe. In other embodiments, the middle gate 200 is polysilicon, or certainly may be metal gate.

In step 3, first sidewall spacers 1000 are formed on both sides of the middle gate stack, wherein, the width of the first sidewall spacer 1000 is about 2-10 nm, as shown in FIG. 7.

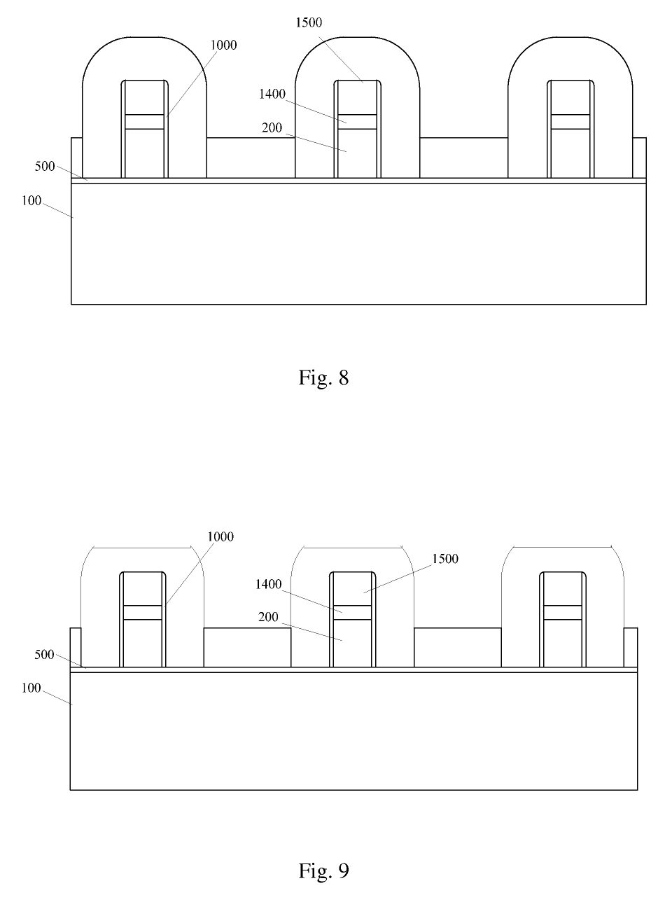

In step 4, a second metal or polysilicon for forming the first gate and the second gate is deposited, as shown in FIG. 8.

In step 5, the deposited second gate metal or polysilicon is scattered by implantation, for example, at a temperature of 70˜100 k, using Xe at an energy of 1e14˜1e16, with incident angle of 30˜70 degree, to planarize the top of the second gate metal or polysilicon on the middle gate 200. FIG. 9 is the schematic diagram after planarization. In one embodiment of the present invention, the first metal and the second metal may be Ti, TiN, TiAlN or Al. Certainly, in other embodiments of the present invention, other planarization methods may be applied, for example the method of filling insulation layer, performing chemical mechanical polishing (CMP) and then stripping the filled insulation layer.

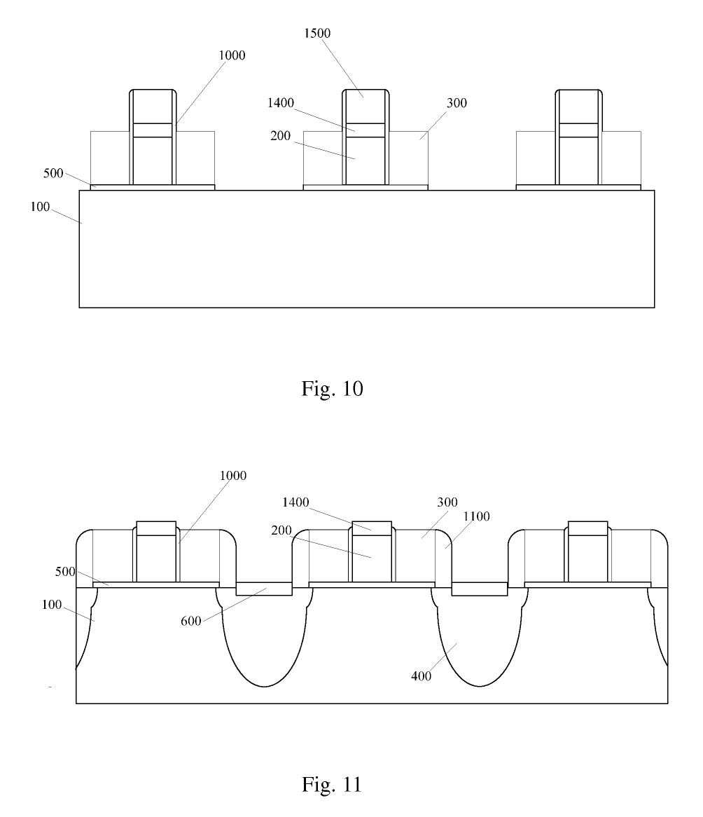

In step 6, the second gate metal or polysilicon is anisotropically etched to form the first and second gates 300, and the middle gate stack is exposed, as shown in FIG. 10.

In step 7, the non-metal filling layer 1500 and the first sidewall spacers 1000 on both sides of the non-metal filling layer 1500 are etched. Then, according to traditional technology, the second sidewall spacers 1100 are formed, extension/halo implantation is carried out, and the source/drain regions 400 are formed by source/drain region implantation (alternatively, after extension/halo implantation, thickening the second sidewall spacers 1100, and then implanting the source/drain regions), and metal silicide layer 600 is formed by metal silicidation in the source/drain regions 400, as shown in FIG. 11.

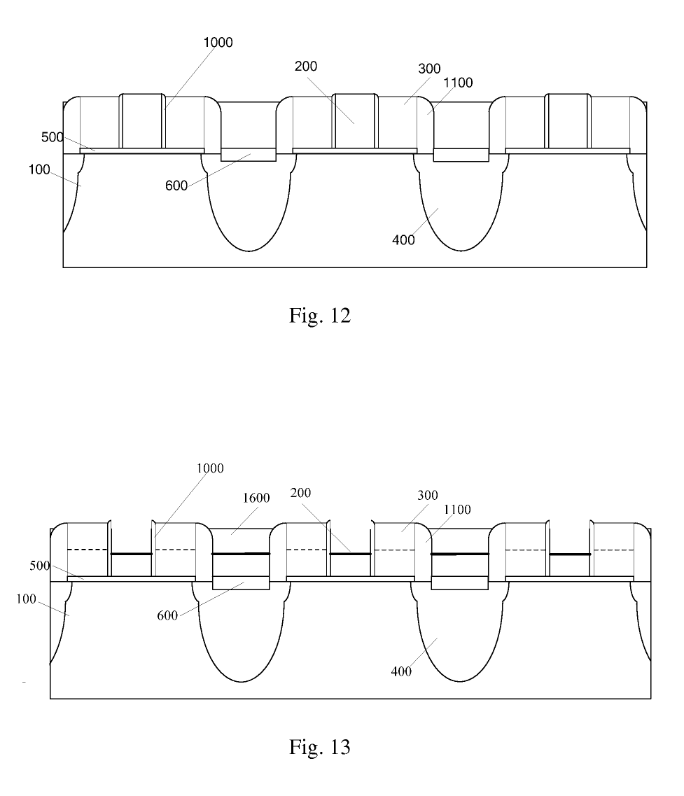

In step 8, a third metal is filled in and chemical mechanical polishing (CMP) is carried out, as shown in FIG. 12 (Note: The middle gate is not in this figure, but it is supposed to be). In one embodiment of the present invention, the third metal may be W, Al, or Cu.

In step 9, the oxide layer 1400 on the middle gate 200 is etched away, as shown in FIG. 12.

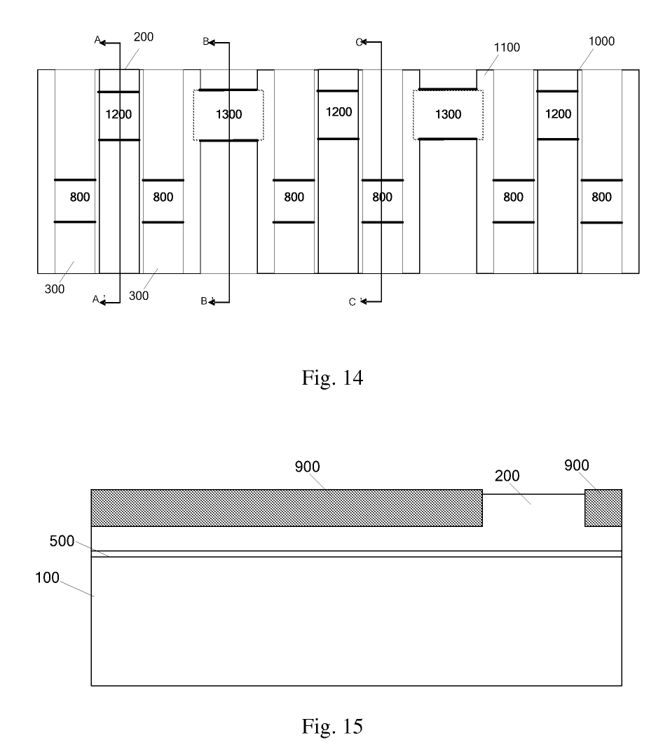

In step 10, a first contact hole region 1200 for connecting the middle gate 200, second contact hole regions 800 for connecting the first and second gates 300, and third contact hole regions 1300 for connecting the source/drain regions 400 are patterned, wherein, a part of the first metal or polysilicon, the second metal or polysilicon, or the third metal under the non-contact hole regions are etched away, for example, half of which are etched away, and then filled by nitride 900 (or other insulation materials), for example, silicon nitride. In particular, a part of the first metal or polysilicon forming the middle gate 200 outside the first contact hole region 1200 is etched by self-aligned technology so that at least a part of the first metal or polysilicon under the first contact hole region 1200 is higher than the first metal or polyoutside the first contact hole region 1200, that is, having an L-shaped or T-shaped contact. In the same way, a part of the second metal or polysilicon forming the first and second gates 300 outside the second contact hole regions 800 is etched away so that at least a part of the second metal or polysilicon under the second contact hole regions 800 is higher than the second metal or polysilicon outside the second contact hole regions 800. Similarly, a part of the third metal 1600 is etched away outside the third contact hole regions 1300 so that at least a part of the third metal under the third contact hole regions 1300 is higher than the third metal 1600 outside the third contact hole regions 1300. FIG. 13 is the cross-section view of an embodiment of the present invention after being etched, FIG. 14 is the top view of an embodiment of the present invention after being etched, and FIGS. 15-17 are cross-section views of FIG. 14 along A-A′ line, B-B′ line, and C-C′ line, respectively. As can be seen from the figures, the first metal or polysilicon, the second metal or polysilicon and the third metal have L-form or T-form contact.

In step 11, oxide 900 is filled, chemical mechanical polishing is carried out, and then the first metal layer used for connection is deposited after patterning, as shown in FIG. 1 and FIG. 2 which are the finally formed NAND structure of the present invention.

The present invention provides a new NAND structure and a method of manufacturing the same. With the NAND structure, about 30-50% area of the chip may be effectively reduced. Furthermore, embodiments of the present invention apply the self-aligned contact hole forming technology, therefore, additional contact hole landing pad is not needed. At the same time, the embodiments illustrated by the present invention are substantially suitable for any current advanced VLSI CMOS technique, for example HKMG (high-K metal gate) or PolySiON (polysilicon/silicon oxynitride), gate-first or gate-last technique and so on, therefore, the NAND structure and the manufacturing method thereof provided by the present invention may have universal applications.

Although the embodiments of the present invention have been illustrated and described, it is readily apparent to those having ordinary skill in the art that various alternations, modifications and substitutions may be made to the embodiments without departing from the principle and spirit of the present invention. The scope of the present invention is defined equivalently by the appended claims of the present invention.

1. A NAND gate structure, comprising:
a substrate;
a gate insulation layer formed on the substrate;
a source/drain region formed in the substrate;
a middle gate formed on the gate insulation layer, and
a first gate and a second gate on each side of the middle gate, first sidewall spacers between the first gate and the middle gate and between the second gate and the middle gate, and second sidewall spacers outside the first gate and the second gate, wherein, a first contact hole region is provided on the middle gate, second contact hole regions are provided respectively on the first gate and the second gate, and the first contact hole region and the second contact hole regions are in staggered arrangement.

2. The NAND structure according to claim 1, wherein the width of the first sidewall spacer is less than that of the second sidewall spacer.

3. The NAND structure according to claim 1, wherein the first contact hole region is connected with the middle gate through a first metal or polysilicon, wherein, at least a part of the first metal or polysilicon under the first contact hole region is higher than the first metal or polysilicon outside the first contact hole region.

4. The NAND structure according to claim 1, wherein the second contact hole regions are connected with the first gate or the second gate through a second metal or polysilicon, wherein, at least a part of the second metal or polysilicon under the second contact hole regions is higher than the second metal or polysilicon outside the second contact hole regions.

5. The NAND structure according to claim 1, further comprising: third contact hole regions formed, respectively, on the source region and the drain region, which are connected with the source/drain region through a third metal, wherein, at least a part of the third metal under the third contact hole regions is higher than the third metal outside the third contact hole regions.

6. The NAND structure according to claim 5, wherein a metallic silicide layer is further comprised between the source/drain region and the third metal.

7. The NAND structure according to claim 4, wherein the first metal or polysilicon, the second metal or polysilicon, or the third metal has an L-shaped or T-shaped contact.

8. The NAND structure according to claim 5, wherein the third metal is W, Al or Cu.

9. The NAND structure according to claim 3, wherein the first metal or second metal is Ti, TiN, TiAlN or Al.

10. A storage device, which is characterized in that comprising a plurality of NAND structures according to claim 1.

11. A method of forming NAND structure, comprising the following steps:
forming a substrate;
forming a gate insulation layer on the substrate;
forming a middle gate on the gate insulation layer, and forming a first gate and a second gate on both sides of the middle gate, wherein first sidewall spacers are formed between the first gate and the middle gate and between the second gate and the middle gate, and second sidewall spacers are formed outside the first gate and the second gate;
forming a source/drain region in the substrate;
forming a first contact hole region on the middle gate, second contact hole regions on the first gate and the second gate, and third contact hole regions on the source/drain region, wherein, the first contact hole region and the second contact hole regions are in staggered arrangement.

12. The method of forming NAND structure according to claim 11, wherein the step of forming the first gate and the second gate comprises the following steps:
forming the first sidewall spacers on both sides of the middle gate, and then depositing the second gate metal or polysilicon;
carrying out scattering implantation to the deposited second metal or polysilicon to planarize the top of the second gate metal or polysilicon on the middle gate;
forming the first gate and the second gate by anisotropically etching the second gate metal or polysilicon, and exposing the middle gate.

13. The method of forming NAND structure according to claim 11, wherein the width of the first sidewall spacers is smaller than that of the second sidewall spacers.

14. The method of forming NAND structure according to claim 11, wherein the first contact hole region is connected with the middle gate through the first metal or polysilicon, wherein, at least a part of the first metal or polysilicon under the first contact hole region is higher than the first metal or polysilicon outside the first contact hole region.

15. The method of forming NAND structure according to claim 11, wherein the second contact hole regions are connected with the first gate and the second gate through the second metal or polysilicon, wherein, at least a part of the second metal or polysilicon under the second contact hole regions are higher than the second metal or polysilicon outside the second contact hole regions.

16. The method of forming NAND structure according to claim 11, wherein the third contact hole regions are connected with the source/drain region through the third metal, wherein, at least a part of the third metal under the third contact hole regions is higher than the third metal outside the third contact hole regions.

17. The method of forming NAND structure according to claim 11, further comprising: forming a metal silicide layer between the source/drain region and the third metal.

18. The method of forming the NAND structure according to any one of claims 14-16, wherein the first metal or polysilicon, the second metal or polysilicon, or the third metal has an L-shaped or T-shaped contact.

19. The method of forming NAND structure according to claim 11, wherein the third metal is W, Al or Cu.

20. The method of forming NAND structure according to claim 11, wherein the first metal or the second metal is Ti, TiN, TiAlN or Al.
